(19) United States
(12) Patent Application Publication
(10) Pub. No.: US 2026/0031160 A1
(43) Pub. Date: Jan. 29, 2026

(54) SELECTIVE READ DISTURB REFRESH OPERATIONS IN A MEMORY SYSTEM

(71) Applicant: Micron Technology, Inc., Boise, ID (US)

(72) Inventors: Xuan Liu, Shanghai (CN); Bo Zhou, Shanghai (CN)

(21) Appl. No.: 19/270,275

(22) Filed: Jul. 15, 2025

Related U.S. Application Data
(60) Provisional application No. 63/675,643, filed on Jul. 25, 2024.

(51) Int. Cl. G11C 16/34; G11C 16/28; G11C 29/52

(52) U.S. Cl. CPC G11C 16/3431; G11C 16/28; G11C 29/52

(57) ABSTRACT

Methods, systems, and devices for selective read disturb refresh operations in a memory system are described. A memory system may determine, for a set of memory cells, a first quantity of memory cells of the set of memory cells that are associated with having a threshold voltage greater than a reference threshold voltage. The memory system may read the set of memory cells, in response to an error metric for the set of cells satisfying a threshold error metric, to determine a second quantity of memory cells of the set of memory cells that have a threshold voltage greater than the reference threshold voltage. And the memory system may determine whether to perform a refresh operation on the set of memory cells in accordance with a difference between the first quantity of memory cells and the second quantity of memory cells.

### CROSS REFERENCE

The present application for patent claims priority to U.S. Patent Application No. 63/675,643 by Liu et al., entitled “SELECTIVE READ DISTURB REFRESH OPERATIONS IN A MEMORY SYSTEM,” filed Jul. 25, 2024, which is assigned to the assignee hereof, and which is expressly incorporated by reference in its entirety herein.

### TECHNICAL FIELD

The following relates to one or more systems for memory, including selective read disturb refresh operations in a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports selective read disturb refresh operations in a memory system in accordance with examples as disclosed herein.

FIG. 2 shows an example of threshold voltage distributions that support selective read disturb refresh operations in a memory system in accordance with examples as disclosed herein.

FIG. 3 shows an example of a process flow that supports selective read disturb refresh operations in a memory system in accordance with examples as disclosed herein.

FIG. 4 shows a block diagram of a memory system that supports selective read disturb refresh operations in accordance with examples as disclosed herein.

FIG. 5 shows a flowchart illustrating a method or methods that support selective read disturb refresh operations in a memory system in accordance with examples as disclosed herein.

### DETAILED DESCRIPTION

A memory system may include multi-level cells that store multiple bits (e.g., two or more bits) by being programmed to one of multiple threshold voltages. Such cells may be read by applying multiple read voltages and determining the current flow through the cells for the different read voltages. Due to the organization of the memory cells, cells that are not selected for a read operation may still be affected by the read voltages in some cases. For example, unselected cells may be subject to a phenomenon referred to as read disturb in which the cells experience an increase in threshold voltage that accumulates over read operations, resulting in errors in the unselected cells. To remedy read disturb errors, the memory system may perform a read disturb (RD) refresh operation in which data is copied from one block to another block. The memory system may perform an RD refresh operation on a set of memory cells if an error scan reveals that the set of memory cells has a threshold error metric. But the errors detected by the error scan may be due to phenomena other than read disturb, such as slow charge loss, that are remediated by lower-latency, lower-overhead operations than RD refresh operations. In such cases, the memory system may perform unnecessary RD refresh operations, decreasing system performance (e.g., increasing latency, increasing power consumption).

According to the techniques described herein, a memory system may improve system performance by differentiating between read disturb errors and other types of errors so that the memory system can selectively perform RD refresh operations. To do so, the memory system may determine, for a set of memory cells, an initial quantity of the set of memory cells that have, or are expected to have, threshold voltages above a reference threshold voltage. The memory system may then perform an error scan operation to determine if the set of memory cells has a sufficiently severe error metric to justify an RD refresh operation. In this way, the memory system may not indiscriminately perform the RD refresh operation. Rather, the memory system may determine a new quantity of the set of memory cells have threshold voltages above the reference threshold voltage. If the difference between the initial quantity and the new quantity is less than a threshold difference, indicating that the errors are not generally due to read disturb (e.g., some threshold of errors are not due to read disturb), the memory system may skip the RD refresh operation and/or perform different corrective action. Otherwise, the memory system may perform the RD refresh operation. Thus, the memory system may selectively perform RD refresh operations.

In addition to applicability in memory systems as described herein, techniques for selectively performing read disturb refresh operations may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

In addition to applicability in memory systems as described herein, techniques for selectively performing read disturb refresh operations may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving data transfer between devices, among other benefits.

Features of the disclosure are illustrated and described in the context of systems, devices, and circuits. Features of the disclosure are further illustrated and described in the context of threshold voltage distributions, a process flow, a device diagram, and a flowchart.

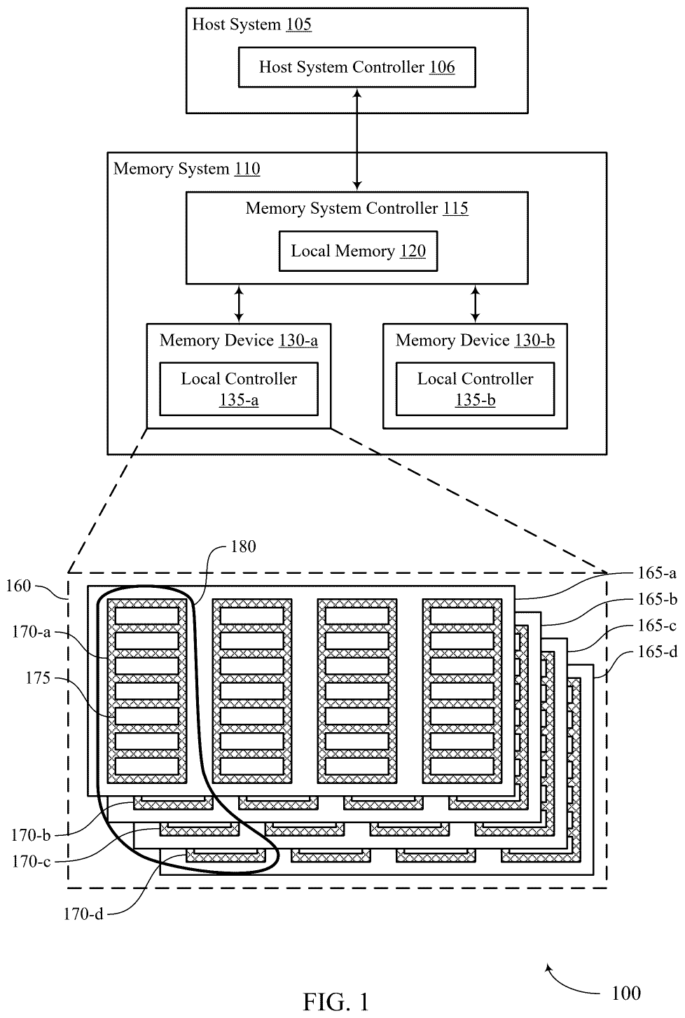

FIG. 1 shows an example of a system 100 that supports selective read disturb refresh operations in a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IOT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

As noted, the logic state(s) of the bit(s) stored by a cell of the memory system 110 may be represented by the threshold voltage of the cell. For example, the memory system 110 may include memory cells that store multiple bits by being programmed to one of multiple threshold voltage levels. As an illustration, a single-level cell (SLC) may be programmed to one of two threshold voltage levels each representative of a different logic state for one bit. As anther illustration, a tri-level cell (TLC) may be programmed to one of eight threshold voltage levels (denoted L0 through L7) each representative of a different combination of logic states for three bits. A memory cell may be read by applying a read voltage to the memory cell and determining the threshold voltage of the memory cell by evaluating the current (or lack thereof) that flows through the memory cell in response to the applied read voltage. In the case of multi-level cells, such as TLCs, a memory cell may be applied with multiple read voltages to determine the threshold voltage of the memory cell.

Over time, the cells in the memory system 110 may experience various phenomena that shift the threshold voltages of the cells. For example, the cells may experience read disturb that causes the threshold voltage of the cells to increase. Cells with lower threshold voltages (e.g., cells programmed with the L0 threshold voltage) may be more susceptible to read disturb than cells with higher threshold voltages. As another example, the cells may experience slow charge loss (SCL) that causes the threshold voltage of the cells to decrease. Because both read disturb and slow charge loss shift the threshold voltages of cells, both read disturb and slow charge loss may result in errors.

The memory system 110 may employ various maintenance operations to mitigate the effects of phenomena such as read disturb and slow charge loss. For example, the memory system 110 may perform RD refresh operations in which data from a set of memory cells suffering from read disturb is copied to another set of memory cells. As another example, the memory system 110 may perform block family error avoidance (BFEA) operations that avoid, reduce, or reverse the effects of slow charge loss. An RD refresh operation may be triggered for a set of memory cells if the memory system 110 detects that the set of memory cells has a threshold error metric. But the errors in the set of memory cells may be overall due to slow charge loss rather than read disturb, and thus may be resolvable by use of a different maintenance operation (e.g., a BFEA operation) that has lower latency and overhead relative to the RD refresh operation. In such cases, performance of an RD refresh operation may negatively impact performance of the memory system 110.

According to the techniques described herein, the memory system 110 may improve performance by selectively performing RD refresh operations. For example, the memory system 110 (e.g., via the memory system controller 115) may determine whether to perform a RD refresh operation on a set of memory cells if the memory system 110 determines that the error metric for the set of memory cells is due primarily to read disturb as opposed to other phenomena that effect threshold voltages. To determine the whether read disturb is the primary cause of the error metric, the memory system 110 may employ a process that allows the memory system 110 to determine the quantity of L0 cells (which may be most susceptive to read disturb) whose threshold voltages have increased above a threshold reference voltage. If the quantity is sufficiently high, the memory system 110 may perform the RD refresh operation. Otherwise, the memory system 110 may skip (e.g., refrain from performing) the RD refresh operation and implement other actions.

The system 100 may include any quantity of non-transitory computer readable media that support selective read disturb refresh operations in a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

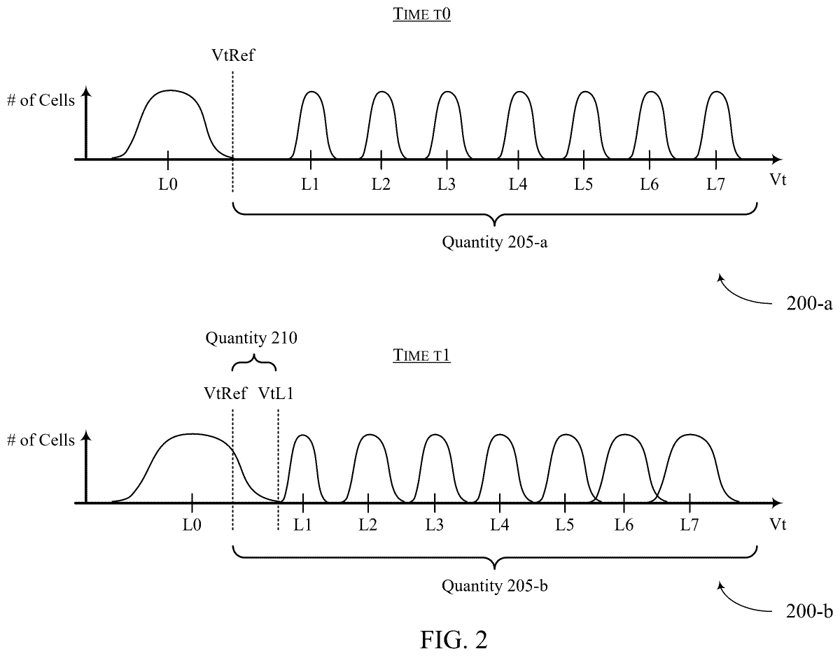

FIG. 2 shows an example of threshold voltage distributions 200 that support selective read disturb refresh operations in a memory system in accordance with examples as disclosed herein. The threshold voltage distributions 200 may include threshold voltage distribution 200-a and threshold voltage distribution 200-b. The threshold voltage distribution 200-a may represent the threshold voltages of a set of memory cells (e.g., one or more blocks of memory cells) at an initial time t0. The threshold voltage distribution 200-b may represent the threshold voltage levels of the set of memory cells at a later time t1 that is after the initial time t0. The set of memory cells may be TLC memory cells and thus may be programmed to one of eight threshold voltage levels denoted L0 through L7, where each threshold voltage level represents a different combination of logic values for three bits. Due to imperfections in the memory system, the cells programmed to a particular threshold voltage level may have actual threshold levels that are slightly different than the target threshold voltage level, resulting in distributions of threshold voltages around the target threshold voltage levels as shown.

The memory system may implement the techniques described herein to determine a quantity 210 of cells (represented by the area under the L0 curve between VtRef and VIL1) whose threshold voltages shift above a reference threshold voltage between time to and time t1, thus indicating the quantity of cells that have experienced read disturb. If the quantity 210 satisfies a threshold (e.g., is greater than or equal to the threshold), the memory system may perform an RD refresh operation. Otherwise, the memory system may refrain from performing the RD refresh operation. In such examples, the memory system may perform another type of maintenance operation, such as a BFEA operation, to remediate threshold voltage shifts due to other phenomena such as slow charge loss.

For time t0, the memory system may determine the quantity 205-a of cells with threshold voltages greater than a reference threshold voltage, VtRef. VtRef may be between L0 (e.g., the lowest threshold voltage level) and LI (e.g., the second lowest threshold voltage level). So, VtRef may be used to differentiate between cells programmed with threshold voltage L0 and cells programmed with threshold voltages greater than L0. The memory system may determine the quantity 205-a by reading the set of memory cells using the reference voltage VtRef. In some examples, the read operation may be internally triggered by the memory system (e.g., independent of the host system) and may be a “dummy” read operation in that the memory system may refrain from returning data read during the read operation to the host system. Because a single read voltage (e.g., VtRef) can be used to detect the first quantity 205-a, similar to an SLC read operation, the read operation may be referred to as a dummy SLC read operation. In some examples, the quantity 205-a may be an average quantity determined for the set of memory cells over multiple read operations using the reference voltage VtRef.

To determine, for time t1, whether to perform an RD refresh operation, the memory system may re-determine the quantity 205-b of cells with threshold voltages greater than the reference threshold voltage VtRef. The memory system may determine the quantity 205-b by re-reading (e.g., via a dummy read operation) the set of memory cells using the reference voltage VtRef. The memory system may then compare the quantity 205-a with the quantity 205-b and determine whether to perform the RD refresh operation based on (e.g., in accordance with) a difference (represented by quantity 210) between quantity 205-a and quantity 205-b. For example, the memory system may determine to perform the RD refresh operation if the difference between quantity 205-a and quantity 205-b is greater than a threshold difference (indicating that the set of memory cells has experienced read disturb severe enough to warrant remediation). Otherwise, the memory system may determine to skip (e.g., refrain from performing) the RD refresh operation and may perform one or more other operations.

In an alternative, the memory system may use a predetermined value instead of the quantity 205-a. For example, the memory system may determine an expected quantity, N_Expected, of cells with threshold voltages greater than the reference threshold voltage VtRef. The expected quantity may be a predetermined value that is based on (e.g., in accordance with) a randomizer used by the memory system to distribute the cells between the eight target threshold levels. For example, if the randomizer is configured to evenly distribute the cells between the eight target threshold levels (such that each level has ⅛ of the cells), the expected quantity N_Expected of cells with threshold voltages may be ⅞ of the total quantity of cells in the set of cells. Use of a predetermined value instead of quantity 205-a may decrease the latency and overhead of the techniques described herein (e.g., because the initial reading of the set of memory cells can be avoided) but may not be as accurate.

To determine, for time t1, whether to perform an RD refresh operation, the memory system may determine the quantity 205-b of cells with threshold voltages greater than the reference threshold voltage VtRef. The memory system may determine the quantity 205-b by reading (e.g., via a dummy read operation) the set of memory cells using the reference threshold voltage VtRef. In some examples, the memory system calibrate the reference threshold voltage VtRef before using the reference threshold voltage VtRef to read the set of memory cells for time t1. To do so, the memory system may read the set of memory cells using the reference threshold voltage VtRef before time t1 to confirm that the reference threshold voltage VtRef is at the appropriate level for the technique. For example, the memory system may read the set of memory cells for time to using the reference threshold voltage VtRef and compare the quantity 205-a with N_Expected. If the difference between quantity 205-a and N_Expected is below a threshold, the memory system may select the threshold voltage VtRef for use. Otherwise, the memory system may adjust the threshold voltage VtRef and repeat the calibration process until the difference between quantity 205-a and N_Expected is below the threshold.

After setting the reference threshold voltage VtRef, the memory system may compare the quantity N_Expected with the quantity 205-b and determine whether to perform the RD refresh operation based on (e.g., in accordance with) a difference between quantity N_Expected and the quantity 205-b. For example, the memory system may determine to perform the RD refresh operation if the difference between quantity N_Expected and the quantity 205-b is greater than the threshold difference (indicating that the set of memory cells has experienced read disturb severe enough to warrant remediation). Otherwise, the memory system may determine to skip (e.g., refrain from performing) the RD refresh operation and may perform one or more other operations.

In some examples, the memory system may condition the determination of the quantity 205-b on an error metric for the set of memory cells, a cross-temperature associated with the set of memory cells, or both. For example, the memory system may determine the quantity 205-b if an error metric for the set of memory cells is greater than a threshold error metric, which may be determined by performing an error scan operation on the set of memory cells. The error scan operation may involve reading the set of memory cells to determine the content stored in the set of memory cells and performing an error detection operation to determine an error metric for the set of memory cells based on (e.g., in accordance with) the content. In some examples, performance of the error scan operation for the set of memory cells may be triggered by the memory system determining that a threshold quantity of read operations (e.g., x read operations, where x is a positive integer) have been performed on the set of memory cells (or on the memory system in general) since the most recently performed error scan operation for the set of memory cells (or for the memory system in general).

In some examples, the error metric may be a raw bit error rate (RBER) that represents the rate of errors in the set of memory cells. The RBER may be calculated by dividing a quantity of errors for the set of memory cells by the total quantity of memory cells in the set of memory cells.

If the error metric for the set of memory cells is greater than the threshold error metric, the memory system may evaluate the cross-temperature associated with the set of memory cells and condition the determination of the quantity 205-b (and subsequent comparison) on the cross-temperature. The cross-temperature of the set of memory cells may be the difference between the write temperature for a subset of memory cells of the set of memory cells and a read temperature for the subset of memory cells, where the write temperature refers to the temperature of the memory system during a write operation for the subset of memory cells, and where the read temperature refers to the temperature of the memory system during a subsequent read operation for the subset of memory cells. Larger cross-temperatures may be associated with more errors than smaller cross-temperatures.

If the cross-temperature for the set of memory cells is less than a threshold cross-temperature (indicating that the error metric is not primarily due to cross-temperature issues), the memory system may determine the quantity 205-b and perform the comparison between the quantity 205-b and the quantity 205-a or the quantity N_Expected. Otherwise, if the cross-temperature for the set of memory cells is greater than a threshold cross-temperature (indicating that the error metric is primarily due to cross-temperature issues), the memory system may refrain from determining the quantity 205-b. Thus, the memory system may selectively perform RD refresh operations, which may improve the efficiency of the memory system, among other benefits.

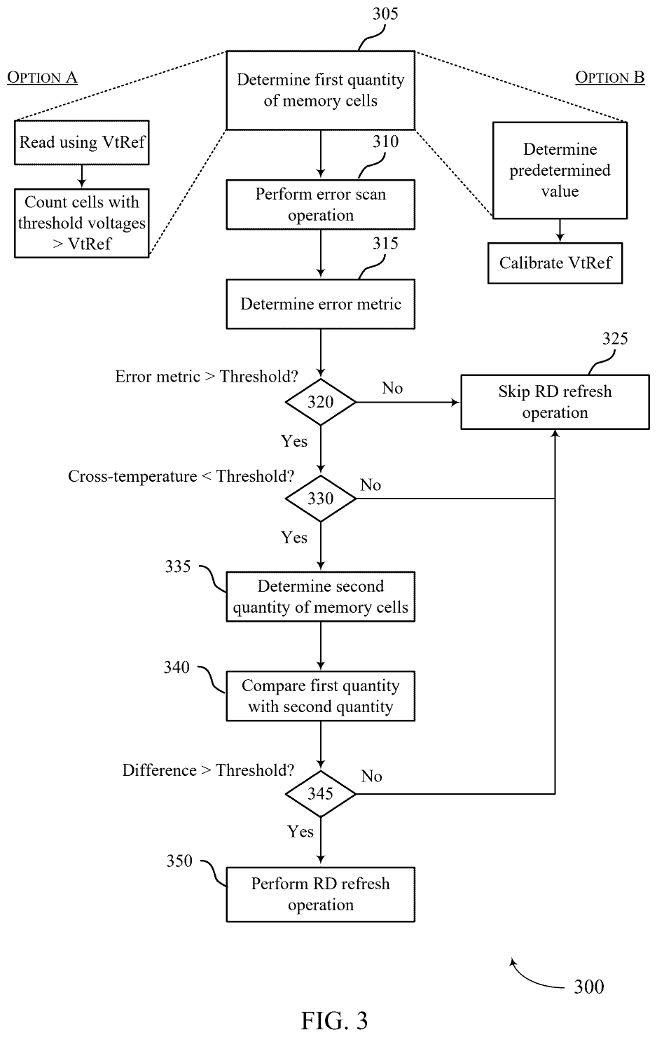

FIG. 3 shows an example of a process flow 300 that supports selective read disturb refresh operations in a memory system in accordance with examples as disclosed herein. The process flow 300 may be implemented by a memory system as described herein. The process flow 300 may allow the memory system to selectively perform RD refresh operations when the errors in a set of memory cells are primarily due to read disturb.

Aspects of the process flow 300 may be implemented by one or more controllers, among other components. Additionally, or alternatively, aspects of the process flow 300 may be implemented as instructions stored in one or more memories (e.g., firmware stored in one or more memories coupled with the memory system 110). For example, the instructions, if executed by one or more controllers (e.g., the memory system controller 115, a local controller 135), may cause the one or more controllers (or a device or a system) to perform the operations of the process flow 300.

At 305, a first quantity of memory cells may be determined (e.g., by the memory system). In a first option, denoted Option A, the first quantity of memory cells may be the quantity of memory cells (e.g., quantity 205-a) with threshold voltages greater than the reference threshold voltage VtRef at time to. In Option A, the memory system may determine the first quantity by reading the set of memory cells using the reference threshold voltage VtRef and counting the quantity of cells with threshold voltages greater than the reference threshold voltage VtRef. In a second option, denoted Option B, the first quantity of memory cells may be the quantity of memory cells (e.g., quantity N_Expected) expected to have threshold voltages greater than the reference threshold voltage VtRef at time to. In Option B, the memory system may determine the first quantity by determining a predetermined value associated with the distribution of threshold voltages (e.g., for levels L0 through L7) targeted by a randomizer of the memory system. In some examples, Option B may include the memory system calibrating the reference threshold voltage VtRef based on (e.g., in accordance with) the predetermined value as described herein.

At 310, an error scan operation may be performed (e.g., by the memory system). The error scan operation may include reading the set of memory cells to determine the content stored in the set of memory cells and performing an error detection operation to determine errors in the set of memory cells based on (e.g., in accordance with) the content. In some examples, performance of the error scan operation may be in accordance with a threshold quantity of read operations having been performed (on the set of memory cells or the by the memory system) since performance of the most recent error scan operation). For example, the error scan operation may be performed every x read operations, where x is a positive integer.

At 315, an error metric for the set of memory cells may be determined (e.g., by the memory system) in accordance with the error scan operation. In some examples, the error metric may be a RBER that represents the rate of errors in the set of memory cells.

At 320, it may be determined (e.g., by the memory system) whether the error metric satisfies (e.g., is greater than) a threshold error metric. If, at 320, it is determined that the error metric does not satisfy (e.g., is not greater than) the threshold error metric, the memory system may, at 325, skip (e.g., refrain from performing) a RD refresh operation on the set of memory cells. If, at 320, it is determined that the error metric satisfies (e.g., is greater than) the threshold error metric, the process flow 300 may proceed to 330.

At 330, it may be determined (e.g., by the memory system) whether a cross-temperature associated with set of memory cells satisfies (e.g., is greater than) a threshold cross-temperature. If, at 330, it is determined that the cross-temperature does not satisfy (e.g., is not greater than) the threshold cross-temperature, the memory system may, at 325, skip (e.g., refrain from performing) a RD refresh operation on the set of memory cells. If, at 330, it is determined that the cross-temperature satisfies (e.g., is greater than) the threshold cross-temperature, the process flow 300 may proceed to 335.

At 335, a second quantity of memory cells may be determined (e.g., by the memory system). The second quantity of memory cells (e.g., quantity 205-b) may be the quantity of memory cells with threshold voltages greater than the reference threshold voltage VtRef at time t1, where time t1 occurs after time to. The memory system may determine the second quantity by reading the set of memory cells using the reference threshold voltage VtRef and counting the quantity of cells with threshold voltages greater than the reference threshold voltage VtRef.

At 340, the first quantity may be compared with the second quantity and a difference between the first quantity and the second quantity may be determined in accordance with the comparison. For example, the memory system may subtract the second quantity from the first quantity. In some examples, it may be determined whether the difference between the first quantity and the second quantity is positive or negative. A positive difference (associated with the first quantity being less than the second quantity) may indicate that the error metric is primarily due to read disturb. A negative difference (associated with the first quantity being greater than the second quantity) may indicate that the error metric is primarily due to a phenomenon other than read disturb (e.g., slow charge loss). So, in some examples, the memory system may determine whether the error metric is primarily due to read disturb or slow charge loss in response determining whether the difference is positive or negative.

At 345, it may be determined (e.g., by the memory system) whether difference between the first quantity and the second quantity satisfies (e.g., is greater than or equal to) a threshold difference. If, at 345, it is determined that the difference between the first quantity and the second quantity does not satisfy (e.g., is not greater than or equal to) the threshold difference, the memory system may, at 325, skip performing a RD refresh operation on the set of memory cells. If, at 345, it is determined that the difference between the first quantity and the second quantity satisfies (e.g., is greater than or equal to) the threshold difference, the process flow 300 may proceed to 350.

At 350, a RD refresh operation may be performed (e.g., by the memory system) on the set of memory cells. For example, the memory system may read content from the set of memory cells and write the content (potentially with error correction) to another set of memory cells.

Thus, the memory system to selectively perform RD refresh operations when the errors in a set of memory cells are primarily due to read disturb. Alternative examples of the foregoing may be implemented, where some operations are performed in a different order than described, are performed in parallel, or are not performed at all. In some cases, operations may include additional features not mentioned herein, or further operations may be added. Additionally, certain operations may be performed multiple times or certain combinations of operations may repeat or cycle.

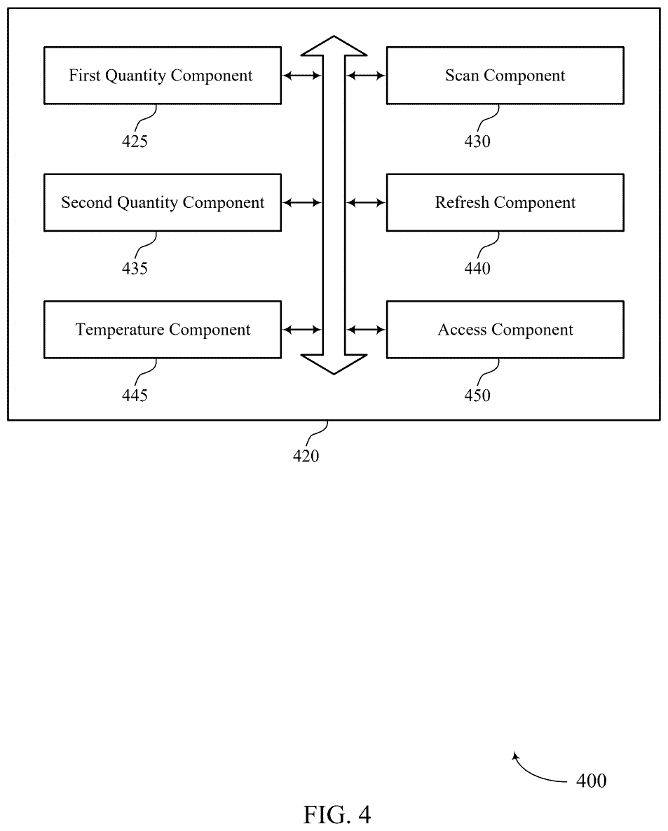

FIG. 4 shows a block diagram 400 of a memory system 420 that supports selective read disturb refresh operations in a memory system in accordance with examples as disclosed herein. The memory system 420 may be an example of aspects of a memory system as described with reference to FIGS. 1 through 3. The memory system 420, or various components thereof, may be an example of means for performing various aspects of selective read disturb refresh operations in a memory system as described herein. For example, the memory system 420 may include a first quantity component 425, a scan component 430, a second quantity component 435, a refresh component 440, a temperature component 445, an access component 450, or any combination thereof. Each of these components, or components of subcomponents thereof (e.g., one or more processors, one or more memories), may communicate, directly or indirectly, with one another (e.g., via one or more buses).

The first quantity component 425 may be configured as or otherwise support a means for determining, for a set of memory cells, a first quantity of memory cells of the set of memory cells that are associated with having a threshold voltage greater than a reference threshold voltage. The scan component 430 may be configured as or otherwise support a means for performing an error scan operation on the set of memory cells, in response to determining the first quantity of memory cells, to determine an error metric for the set of memory cells. The second quantity component 435 may be configured as or otherwise support a means for reading the set of memory cells, in response to the error metric satisfying a threshold error metric, to determine a second quantity of memory cells of the set of memory cells that have a threshold voltage greater than the reference threshold voltage. The refresh component 440 may be configured as or otherwise support a means for determining whether to perform a refresh operation on the set of memory cells in accordance with a difference between the first quantity of memory cells and the second quantity of memory cells.

In some examples, to support determining whether to perform the refresh operation, the refresh component 440 may be configured as or otherwise support a means for determining to perform the refresh operation in response to the difference between the first quantity of memory cells and the second quantity of memory cells satisfying a threshold difference.

In some examples, to support determining whether to perform the refresh operation, the refresh component 440 may be configured as or otherwise support a means for determining to skip the refresh operation in response to the difference between the first quantity of memory cells and the second quantity of memory cells failing to satisfy a threshold difference.

In some examples, the temperature component 445 may be configured as or otherwise support a means for determining whether a difference between a write temperature and read temperature for the set of memory cells is less than or equal to a threshold, where the second quantity of memory cells is determined in response to determining that the difference is less than or equal to the threshold.

In some examples, the first quantity of memory cells is determined in response to reading the set of memory cells using the reference threshold voltage. In some examples, the second quantity of memory cells is read using the reference threshold voltage.

In some examples, the access component 450 may be configured as or otherwise support a means for refraining from communicating data read from the set of memory cells in response to reading the set of memory cells. In some examples, the first quantity of memory cells is equal to a predetermined value.

In some examples, the access component 450 may be configured as or otherwise support a means for reading the set of memory cells using the reference threshold voltage. In some examples, the first quantity component 425 may be configured as or otherwise support a means for determining that the first quantity of memory cells is within a threshold range of a predetermined value, where the reference threshold voltage is selected in response to the first quantity of memory cells being within a threshold range of the predetermined value.

In some examples, the scan component 430 may be configured as or otherwise support a means for determining whether the error metric is due to read disturb or slow charge loss in response determining whether the difference is positive or negative.

In some examples, the set of memory cells includes multi-level cells each configured to store multiple bits using one of multiple threshold voltages. In some examples, the reference threshold voltage is between a lowest threshold voltage of the multiple threshold voltages and a second lowest threshold voltage of the multiple threshold voltages.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

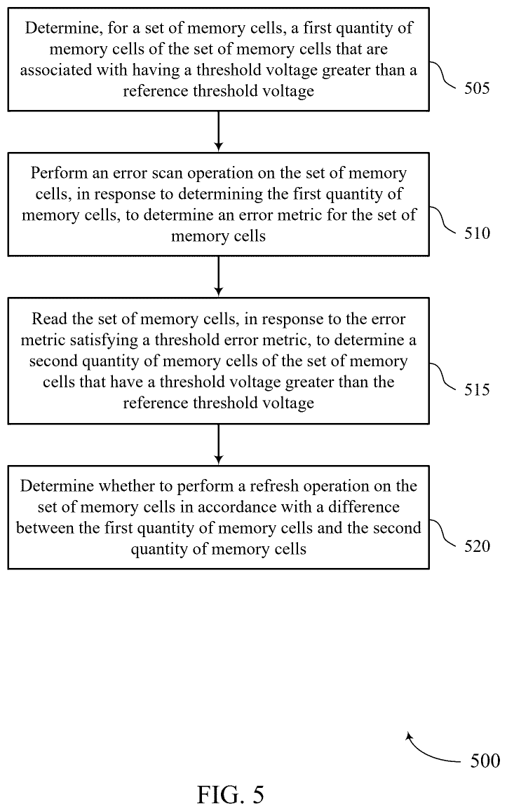

FIG. 5 shows a flowchart illustrating a method 500 that supports selective read disturb refresh operations in a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include determining, for a set of memory cells, a first quantity of memory cells of the set of memory cells that are associated with having a threshold voltage greater than a reference threshold voltage. In some examples, aspects of the operations of 505 may be performed by a first quantity component 425 as described with reference to FIG. 4.

At 510, the method may include performing an error scan operation on the set of memory cells, in response to determining the first quantity of memory cells, to determine an error metric for the set of memory cells. In some examples, aspects of the operations of 510 may be performed by a scan component 430 as described with reference to FIG. 4.

At 515, the method may include reading the set of memory cells, in response to the error metric satisfying a threshold error metric, to determine a second quantity of memory cells of the set of memory cells that have a threshold voltage greater than the reference threshold voltage. In some examples, aspects of the operations of 515 may be performed by a second quantity component 435 as described with reference to FIG. 4.

At 520, the method may include determining whether to perform a refresh operation on the set of memory cells in accordance with a difference between the first quantity of memory cells and the second quantity of memory cells. In some examples, aspects of the operations of 520 may be performed by a refresh component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for determining, for a set of memory cells, a first quantity of memory cells of the set of memory cells that are associated with having a threshold voltage greater than a reference threshold voltage; performing an error scan operation on the set of memory cells, in response to determining the first quantity of memory cells, to determine an error metric for the set of memory cells; reading the set of memory cells, in response to the error metric satisfying a threshold error metric, to determine a second quantity of memory cells of the set of memory cells that have a threshold voltage greater than the reference threshold voltage; and determining whether to perform a refresh operation on the set of memory cells in accordance with a difference between the first quantity of memory cells and the second quantity of memory cells.

Aspect 2: The method, apparatus, or non-transitory computer-readable medium of aspect 1, where determining whether to perform the refresh operation includes operations, features, circuitry, logic, means, or instructions, or any combination thereof for determining to perform the refresh operation in response to the difference between the first quantity of memory cells and the second quantity of memory cells satisfying a threshold difference.

Aspect 3: The method, apparatus, or non-transitory computer-readable medium of any of aspects 1 through 2, where determining whether to perform the refresh operation includes operations, features, circuitry, logic, means, or instructions, or any combination thereof for determining to skip the refresh operation in response to the difference between the first quantity of memory cells and the second quantity of memory cells failing to satisfy a threshold difference.

Aspect 4: The method, apparatus, or non-transitory computer-readable medium of any of aspects 1 through 3, further including operations, features, circuitry, logic, means, or instructions, or any combination thereof for determining whether a difference between a write temperature and read temperature for the set of memory cells is less than or equal to a threshold, where the second quantity of memory cells is determined in response to determining that the difference is less than or equal to the threshold.

Aspect 5: The method, apparatus, or non-transitory computer-readable medium of any of aspects 1 through 4, where the first quantity of memory cells is determined in response to reading the set of memory cells using the reference threshold voltage.

Aspect 6: The method, apparatus, or non-transitory computer-readable medium of aspect 5, where the second quantity of memory cells is read using the reference threshold voltage.

Aspect 7: The method, apparatus, or non-transitory computer-readable medium of any of aspects 5 through 6, further including operations, features, circuitry, logic, means, or instructions, or any combination thereof for refraining from communicating data read from the set of memory cells in response to reading the set of memory cells.

Aspect 8: The method, apparatus, or non-transitory computer-readable medium of any of aspects 1 through 7, where the first quantity of memory cells is equal to a predetermined value.

Aspect 9: The method, apparatus, or non-transitory computer-readable medium of aspect 8, further including operations, features, circuitry, logic, means, or instructions, or any combination thereof for reading the set of memory cells using the reference threshold voltage and determining that the first quantity of memory cells is within a threshold range of a predetermined value, where the reference threshold voltage is selected in response to the first quantity of memory cells being within a threshold range of the predetermined value.

Aspect 10: The method, apparatus, or non-transitory computer-readable medium of any of aspects 1 through 9, further including operations, features, circuitry, logic, means, or instructions, or any combination thereof for determining whether the error metric is due to read disturb or slow charge loss in response determining whether the difference is positive or negative.

Aspect 11: The method, apparatus, or non-transitory computer-readable medium of any of aspects 1 through 10, where the set of memory cells includes multi-level cells each configured to store multiple bits using one of multiple threshold voltages and the reference threshold voltage is between a lowest threshold voltage of the multiple threshold voltages and a second lowest threshold voltage of the multiple threshold voltages.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
determine, for a set of memory cells, a first quantity of memory cells of the set of memory cells that are associated with having a threshold voltage greater than a reference threshold voltage;
perform an error scan operation on the set of memory cells, in response to determining the first quantity of memory cells, to determine an error metric for the set of memory cells;
read the set of memory cells, in response to the error metric satisfying a threshold error metric, to determine a second quantity of memory cells of the set of memory cells that have a threshold voltage greater than the reference threshold voltage; and
determine whether to perform a refresh operation on the set of memory cells in accordance with a difference between the first quantity of memory cells and the second quantity of memory cells.

2. The memory system of claim 1, wherein determining whether to perform the refresh operation comprises the processing circuitry configured to cause the memory system to:
determine to perform the refresh operation in response to the difference between the first quantity of memory cells and the second quantity of memory cells satisfying a threshold difference.

3. The memory system of claim 1, wherein determining whether to perform the refresh operation comprises the processing circuitry configured to cause the memory system to:
determine to skip the refresh operation in response to the difference between the first quantity of memory cells and the second quantity of memory cells failing to satisfy a threshold difference.

4. The memory system of claim 1, wherein the first quantity of memory cells is determined in response to reading the set of memory cells using the reference threshold voltage.

5. The memory system of claim 4, wherein the second quantity of memory cells is read using the reference threshold voltage.

6. The memory system of claim 4, wherein the processing circuitry is further configured to cause the memory system to:
refrain from communicating data read from the set of memory cells in response to reading the set of memory cells.

7. The memory system of claim 1, wherein the first quantity of memory cells is equal to a predetermined value.

8. The memory system of claim 7, wherein the processing circuitry is further configured to cause the memory system to:
read the set of memory cells using the reference threshold voltage; and
determine that the first quantity of memory cells is within a threshold range of a predetermined value, wherein the reference threshold voltage is selected in response to the first quantity of memory cells being within a threshold range of the predetermined value.

9. The memory system of claim 1, wherein the processing circuitry is further configured to cause the memory system to:
determine whether the error metric is due to read disturb or slow charge loss in response determining whether the difference is positive or negative.

10. The memory system of claim 1, wherein the set of memory cells comprises multi-level cells each configured to store multiple bits using one of multiple threshold voltages, and wherein the reference threshold voltage is between a lowest threshold voltage of the multiple threshold voltages and a second lowest threshold voltage of the multiple threshold voltages.

11. A method, comprising:
determining, for a set of memory cells, a first quantity of memory cells of the set of memory cells that are associated with having a threshold voltage greater than a reference threshold voltage;
performing an error scan operation on the set of memory cells, in response to determining the first quantity of memory cells, to determine an error metric for the set of memory cells;
reading the set of memory cells, in response to the error metric satisfying a threshold error metric, to determine a second quantity of memory cells of the set of memory cells that have a threshold voltage greater than the reference threshold voltage; and
determining whether to perform a refresh operation on the set of memory cells in accordance with a difference between the first quantity of memory cells and the second quantity of memory cells.

12. The method of claim 11, wherein determining whether to perform the refresh operation comprises:
determining to perform the refresh operation in response to the difference between the first quantity of memory cells and the second quantity of memory cells satisfying a threshold difference.

13. The method of claim 11, wherein determining whether to perform the refresh operation comprises:
determining to skip the refresh operation in response to the difference between the first quantity of memory cells and the second quantity of memory cells failing to satisfy a threshold difference.

14. The method of claim 11, wherein the first quantity of memory cells is determined in response to reading the set of memory cells using the reference threshold voltage.

15. The method of claim 14, wherein the second quantity of memory cells is read using the reference threshold voltage.

16. The method of claim 14, further comprising:
refraining from communicating data read from the set of memory cells in response to reading the set of memory cells.

17. The method of claim 11, wherein the first quantity of memory cells is equal to a predetermined value.

18. The method of claim 17, further comprising:
reading the set of memory cells using the reference threshold voltage; and
determining that the first quantity of memory cells is within a threshold range of a predetermined value, wherein the reference threshold voltage is selected in response to the first quantity of memory cells being within a threshold range of the predetermined value.

19. The method of claim 11, further comprising:
determining whether the error metric is due to read disturb or slow charge loss in response determining whether the difference is positive or negative.

20. The method of claim 11, wherein the set of memory cells comprises multi-level cells each configured to store multiple bits using one of multiple threshold voltages, and wherein the reference threshold voltage is between a lowest threshold voltage of the multiple threshold voltages and a second lowest threshold voltage of the multiple threshold voltages.

21. A non-transitory computer-readable medium storing code, the code comprising instructions executable by processing circuitry of a memory system to cause the memory system to:
determine, for a set of memory cells, a first quantity of memory cells of the set of memory cells that are associated with having a threshold voltage greater than a reference threshold voltage;
perform an error scan operation on the set of memory cells, in response to determining the first quantity of memory cells, to determine an error metric for the set of memory cells;
read the set of memory cells, in response to the error metric satisfying a threshold error metric, to determine a second quantity of memory cells of the set of memory cells that have a threshold voltage greater than the reference threshold voltage; and
determine whether to perform a refresh operation on the set of memory cells in accordance with a difference between the first quantity of memory cells and the second quantity of memory cells.

22. The non-transitory computer-readable medium of claim 21, wherein the instructions to determine whether to perform the refresh operation are executable by the processing circuitry to cause the memory system to:
determine to perform the refresh operation in response to the difference between the first quantity of memory cells and the second quantity of memory cells satisfying a threshold difference.

23. The non-transitory computer-readable medium of claim 21, wherein the instructions to determine whether to perform the refresh operation are executable by the processing circuitry to cause the memory system to:
determine to skip the refresh operation in response to the difference between the first quantity of memory cells and the second quantity of memory cells failing to satisfy a threshold difference.
